(19) United States
(12) Patent Application Publication
(10) Pub. No.: US 2007/0011565 A1
(43) Pub. Date: Jan. 11, 2007

(54) Method and apparatus for low-density parity check encoding

(75) Inventors: Hyun-jung Kim, Suwon-si (KR); Kyung-geun Lee, Seongnam-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/371,932

(22) Filed: Mar. 10, 2006

(30) Foreign Application Priority Data
Jun. 25, 2005 (KR) 2005-55418

(51) Int. Cl. H03M 13/00

(52) U.S. Cl. 714/758

(57) ABSTRACT

A method of improving the error correcting performance using low-density parity check (LDPC) encoding includes, making an LDPC matrix by arranging non-zero matrices in a series of blockwise columns not to overlap with one another, making at least one LDPC codeword block by generating parity information based on the LDPC matrix, making an error correcting block by accumulating the LDPC codeword block, and interleaving the error correcting block. Accordingly, it is possible to improve the burst error correcting performance in a communications/high-density recording medium system.

### CROSS-REFERENCE TO RELATED APPLICATION

This application claims the benefit of Korean Patent Application No. 200555418, filed Jun. 25, 2005 in the Korean Intellectual Property Office, the disclosure of which is incorporated herein by reference.

### BACKGROUND OF THE INVENTION

1. Field of the Invention

An aspect of the present invention relates to low-density parity check (LDPC) encoding, and more particularly, to a method and apparatus for improving the error correcting performance of LDPC encoding.

2. Description of the Related Art

Low-density parity checking (LDPC) encoding and decoding is one of error correction encoding and decoding techniques applied to the field of wireless communications or applied to the field of optical recording and reproducing. LDPC encoding includes a process of generating parity information using a parity check matrix. A large number of elements of the parity check matrix are 0, and a very minimum number of the elements are 1. In LDPC encoding, encoding is repetitively performed using a sum-product algorithm, thereby improving the error correcting performance.

LDPC encoding is divided into regular LDPC encoding and irregular LDPC encoding. In regular LDPC encoding, the number of 1's is the same in a row and a column of a parity check matrix used in an encoding/decoding process. However, in irregular LDPC encoding, the number of 1's is different in this case. In regular LDPC encoding, the numbers of 1's in each row and each column of the parity check matrix are referred to as a row weight and a column weight, respectively.

LDPC encoding is given by:
H·Cₑ=0 (1),
where “H” denotes a parity check matrix, “0” denotes a zero matrix, “·” denotes an XOR operation and a modular-2 operation, and “Cₑ” denotes a codeword vector that is a column matrix representing a codeword to be encoded. The codeword includes x-bit message words x₁, x₂ . . . , xₓ, and p-bit parity information p₁, p₂, . . . , pₚ.

The parity information p₁, p₂, . . . , pₚ is generated such that each of the message words x₁, x₂, . . . , xₓ satisfies Equation (1). That is, since a binary value of the message word of elements of the parity check matrix H and the codeword vector Cₑ, which is to be encoded, have already been determined, the parity information pᵢ (i=1, 2, . . . , p) can be determined by Equation (1).

LDPC encoding has been described in greater detail in “Good Error-Correction Codes Based on Very Sparse Matrices” (D. J. MacKay, IEEE Trans. on Information Theory, vol. 45, no.2, pp.399-431, 1999).

Meanwhile, interleaving is a technique that provides a solution to a burst error. When a signal passes through a channel in a communications/recording medium system, the burst error that occurs only in a specific point on a signal may occur in the passing signal. The burst error is caused by an external factor to a transfer medium in the communications system and by a scratch on a recording medium in the recording medium system. Since the burst error occurs in a specific point in a bitstream to be transmitted, it is possible to reduce the size of the burst error in the specific point by dispersing information of the bitstream in the specific point to a different position and repositioning it to the original position in a decoding process performed by a receiving side. The reduced error can be recovered using information on the other points in the bitstream where an error does not occur, e.g., parity information.

FIG. 1 illustrates the construction of an LDPC matrix. Referring to FIG. 1, the LDPC matrix has a regular pattern in which each column is equally given a weight of 3 and each row is equally given a weight of 6.

FIG. 2 is a factor graph illustrating the LDPC matrix of FIG. 1. Referring to FIG. 2, the factor graph is comprised of 12 variable nodes and 6 check nodes. A first bit of data is connected to first, second, and fourth parities. Thus, when an error occurs in the first bit, the error can be corrected using the first, second, and fourth parities. When using the LDPC encoding that performs error correction repeatedly, the error is continuously corrected through a more complicated linkage structure. That is, each of the first, second, and fourth parities linked to the first bit is also linked to other bits linked to other parities, and such a linkage is repeated for the other bits.

For instance, when the burst error continuously occurs in the first bit and a second bit, the first bit is error-corrected using the first, second, and fourth parties, and the second bit is error-corrected using the first, second, and fifth parities. Each parity is linked to several bits that are linked to the other bits. Accordingly, the LDPC matrix allows an error in each bit to be corrected using the values of the other bits that are distant from the bit without interleaving, thereby easily correcting errors in a series of bits. For this reason, when a short burst error occurs in a general communications system, the burst error may be corrected only through LDPC encoding without an interleaver.

However, a lot of errors are likely to occur in the next-generation optical recording disc, on which high-density recording is achieved, due to dust, fingerprints, or a scratch. Therefore, it is difficult to correct a long burst error only using a LDPC codeword.

### SUMMARY OF THE INVENTION

According to an aspect of the present invention, there is provided a method of improving the error correcting performance of low-density parity check (LDPC) encoding.

According to one aspect of the present invention, there is provided a low-density parity check encoding method including generating a low-density parity check matrix by arranging non-zero submatrices in a series of blockwise columns such that the non-zero submatrices do not overlap with one another; making at least one low-density parity check codeword block by generating parity information based on the low-density parity check matrix; making an error correcting block by accumulating the low-density parity check codeword block; and interleaving the error correcting block.

According to another aspect of the present invention, the submatrices of the low-density parity check matrix may be arranged such that a cycle-4 phenomenon does not occur in the low-density parity check matrix.

According to another aspect of the present invention, each submatrix of the low-density parity check matrix may be one of a unit matrix and a matrix obtained by shifting the unit matrix by rows or columns.

According to another aspect of the present invention, the interleaving of the error correcting block may include dividing the error correcting block into interleaving blocks, based on the size of each submatrix of the low-density parity check matrix; and interleaving the error correcting block into units of the interleaving blocks.

According to another aspect of the present invention, the interleaving blocks may be obtained by dividing the error correcting block by a multiple of each submatrix of the low-density parity check matrix. The interleaving blocks may be obtained by dividing the error correcting block by a value which is obtained by multiplying the size of each submatrix by a number of blockwise columns in which the non-zero matrices of the low-density parity check matrix do not overlap with one another.

According to another aspect of the present invention, the interleaving of the error correcting block may include interleaving the error correcting block into units of bytes. The interleaving of the error correcting block may include interleaving the error correcting block into units of bits. The interleaving of the error correcting block may include recording the interleaving blocks in the vertical direction and reading them in the horizontal direction.

According to another aspect of the present invention, there is provided a low-density parity check encoding apparatus including a low-density parity check encoder making a low-density parity check matrix by arranging non-zero matrices in a series of blockwise columns such that the non-zero matrices do not overlap with one another, and generating at least one low-density parity check codeword block by generating parity information based on the low-density parity check matrix; and an interleaver making an error correcting block by accumulating the low-density parity check codeword block, and interleaving the error correcting block.2

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 illustrates the structure of a conventional low-density parity check (LDPC) matrix;

FIG. 2 is a factor graph illustrating the LDPC matrix of FIG. 1;

FIG. 3 is a block diagram of an encoding/decoding apparatus used in a communications/recording medium system according to an embodiment of the present invention;

FIG. 4 illustrates an LDPC matrix according to an embodiment of the present invention;

FIG. 5 illustrates an LDPC matrix according to another embodiment of the present invention;

FIG. 6 is an LDPC codeword block according to an embodiment of the present invention;

FIG. 7 illustrates an interleaver on which an LDPC codeword interleaving is performed, according to an embodiment of the present invention;

FIG. 8 is a graph for comparing a conventional error correcting performance with that of an embodiment of the present invention; and

FIG. 9 is a flowchart illustrating LDPC encoding according to an embodiment of the present invention.

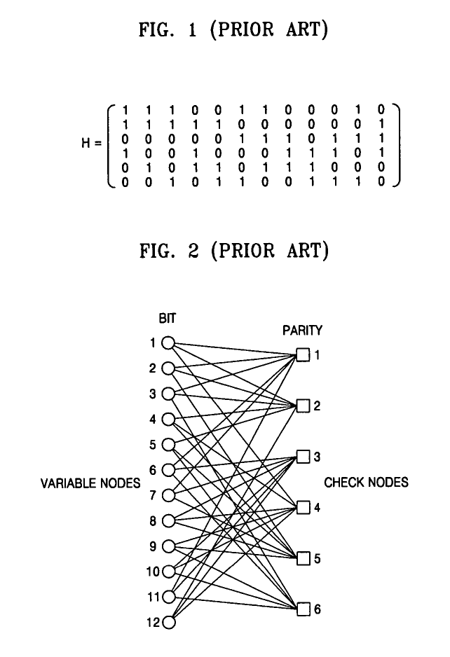

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

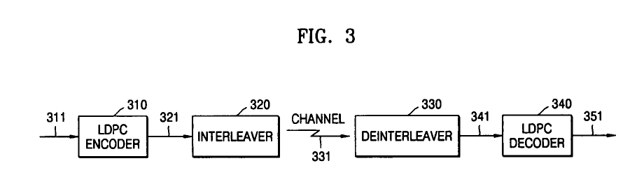

FIG. 3 is a block diagram of an encoding/decoding apparatus used in a communications/recording medium system (in other words, a communication system or a recording medium system) according to an embodiment of the present invention. Referring to FIG. 3, in general, a low-density parity check (LDPC) encoder 310 receives the original message word 311 to be transmitted, and performs LDPC encoding thereon to obtain several codeword vectors 321. In an embodiment of the present invention, an LDPC matrix has submatrices that are unit matrices and matrices obtained by shifting the unit matrices.

Each of the codeword vectors 321 contains the message word 311, and parity information that is generated to satisfy Equation (1). An interleaver 320, which performs interleaving in units of bits, generates an interleaved bitstream 331 by receiving the several codeword vectors 321 from the LDPC encoder 310 to form an error correcting block, dividing the error correcting block into several sub blocks, and properly dispersing the sub blocks to different positions. In the present embodiment, the interleaver 320 interleaves the error correcting block either in a unit of a multiple of the submatrix of the LDPC matrix, or in a unit of the product of the size of each submatrix and the number of a series of blockwise columns of the LDPC matrix, in which non-zero submatrices do not overlap with one another.

The interleaved bitstream 331 is transmitted via a transmission medium, such as air, in the communications system, and recorded in a recording medium and transmitted to a reproducing apparatus in the recording medium system.

In a receiving side or a reproducing apparatus, a deinterleaver 330 receives and deinterleaves the interleaved bitstream 331, and obtains the original codeword vectors 341. An LDPC decoder 340 receives the codeword vectors 341 and generates the original message word 351 according to an LDPC decoding algorithm.

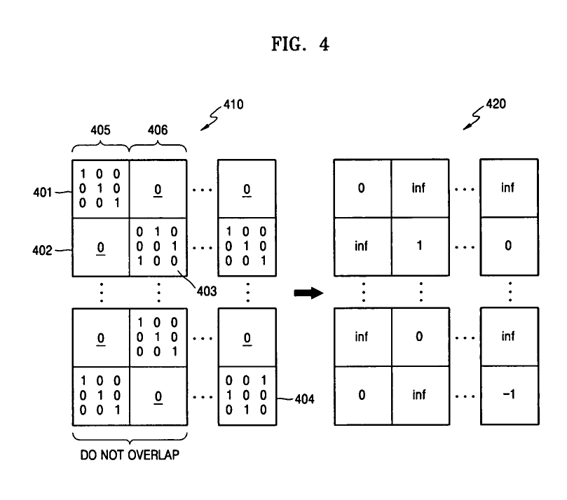

FIG. 4 illustrates an LDPC matrix according to an embodiment of the present invention.

In an embodiment of the present invention, an LDPC matrix is a regular LDPC matrix that is constructed in units of submatrices. The size of each submatrix is determined according to the performance of hardware that performs an operation on the LDPC matrix. Each submatrix is a unit matrix, and a matrix is obtained by shifting rows or columns in the unit matrix, so that the order of the rows or the columns can change.

Referring to FIG. 4, an LDPC matrix 410 includes a series of blockwise columns. The series of the blockwise columns, e.g., blockwise columns 405 and 406, are arranged such that submatrices, each having a value other than 0, that is, non-zero submatrices, do not overlap with one another. In this disclosure, submatrices that do not overlap with one another are non-zero submatrices in a series of blockwise columns arrayed not to be adjacent to each other in the same row.

The LDPC matrix 410 is also arranged such that a cycle-4 phenomenon does not occur therein. The “cycle-4 phenomenon” indicates a phenomenon in which a bit error rate (BER) performance obtained in a decoding process is degraded when 1's that are elements of a parity check matrix are located at special positions. Here, the special positions denote four corners of any rectangle in the parity check matrix. For instance, the cycle-4 phenomenon occurs when 1's are located at positions (2,2), (2,8), (4,8), and (4,2), which form a rectangle when connected to each other. Therefore, the LDPC matrix 410 is arrayed such that a rectangular loop is not formed when non-zero submatrices are connected. That is, the LDPC matrix 410 is formed such that non-zero submatrices are arranged together with previous non-zero submatrices not to cause the cycle-4 phenomenon.

The LDPC matrix 410 includes submatrices 401 through 404. The submatrix 401 is a 3×3 unit matrix, the submatrix 402 is a 3×3 zero matrix, the submatrix 403 is a matrix obtained by shifting elements of the 3×3 unit matrix 401 by 1 to the right side of the 3×3 unit matrix 401, and the submatrix 404 is a matrix obtained by shifting elements of the 3×3 unit matrix 401 by 1 to the left side of the 3×3 unit matrix 401.

In FIG. 4, an LDPC matrix 420 is a simplified representation of the LDPC matrix 410, which indicates each submatrix of the LDPC matrix 410 using a shift value with respect to a unit matrix. In the LDPC matrix 420, “0” denotes the unit matrix 401, “inf” denotes the zero matrix 402, “1” denotes the matrix 403 obtained by shifting the elements of the unit matrix 401 by 1 to the right side of the matrix 401, and “−1” denotes the matrix 404 obtained by shifting the elements of the matrix 401 by 1 to the left side of the matrix 401.

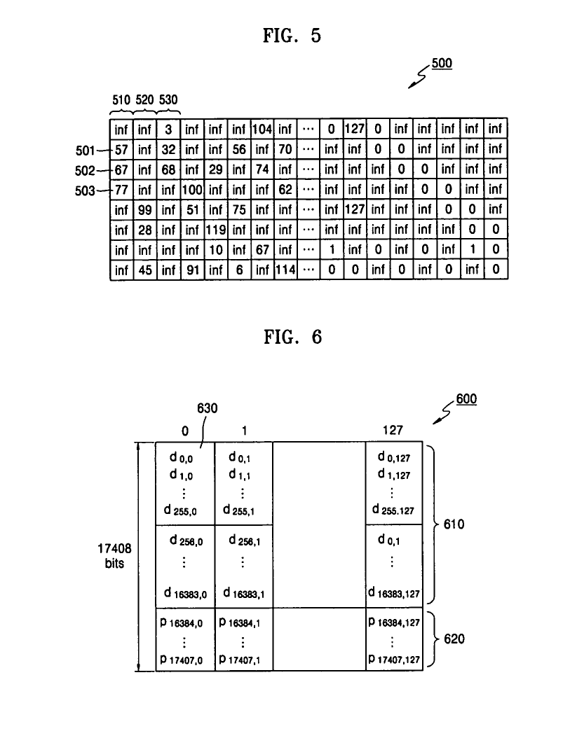

FIG. 5 illustrates an LDPC matrix 500 according to another embodiment of the present invention. The LDPC matrix 500 includes 128×128 submatrices. A blockwise column 510 has eight submatrices that include three non-zero matrices. Similar to the LDPC matrix 420 of FIG. 4, “inf” denotes an 128×128 zero matrix, “0” denotes an 128×128 unit matrix, and values other than 0 denote matrices that are obtained by shifting the 128×128 unit matrix by the values, respectively. The LDPC matrix 500 is formed such that non-zero submatrices in adjacent blockwise columns are arranged not to overlap with one another and the cycle-4 state does not occur throughout the LDPC matrix 500. As will later be explained, the size of a column in which non-zero submatrices in a blockwise column do not overlap with one another, is limited.

To array non-zero submatrices in a series of blockwise columns not to overlap with one another, non-zero submatrices 501 through 503 in a first blockwise column 510 may be located in second through fourth rows thereof, respectively. Three non-zero submatrices in a second blockwise column 520 must be arranged in three of a first and fifth through eighth rows so that they do not overlap with the submatrices 501 through 503 in the first blockwise column 510. Referring to FIG. 5, non-zero submatrices are located in the fifth, sixth, and eighth rows of the second blockwise column 520, respectively. However, to array non-zero submatrices in a third blockwise column 530 not to overlap the non-zero submatrices in the first and second blockwise columns 510 and 520, two of them are arranged in first and seventh rows, respectively, but the other overlaps with one of the non-zero submatrices of the first and second blockwise columns 510 and 520.

Accordingly, referring to FIG. 5, the number L of blockwise columns in which non-zero submatrices do not overlap with one another is two. As will later be described, the number L is related to units into which interleaving is performed, according to an embodiment of the present invention.

In an LDPC matrix in which non-zero submatrices in a series of blockwise columns do not overlap with one another, when a series of errors occur, computing is performed after dispersing the errors to different parity check nodes. Accordingly, it is possible to easily recognize and correct an error in each parity check node, thereby improving an overall error correcting performance of encoding.

When an LDPC code matrix in units of blocks and a data code, according to the LDPC matrix of FIG. 5, are substituted into Equation (1), a parity code is obtained, thereby forming an LDPC codeword consisting of the data code and the parity code.

FIG. 6 illustrates an LDPC codeword block 600 according to an embodiment of the present invention.

In general, a large-capacity interleaver is required to correct a long burst error. Thus, several LDPC codeword blocks are accumulated to perform interleaving thereon. The LDPC codeword block 600 is 17408 bits long, and includes 128 16384-bit data code blocks 610, and 128 1024-bit parity code blocks 620. In FIG. 6, first subscript of each data d and parity code p denotes a bit value, and the other denotes a codeword.

The data code block 610 is divided into 256-bit data sub-blocks, such as a codeword block 630 in a first row of a first column of the data code block 610. The 256-bit data sub-blocks are unit blocks into which interleaving is performed, according to an embodiment of the present invention.

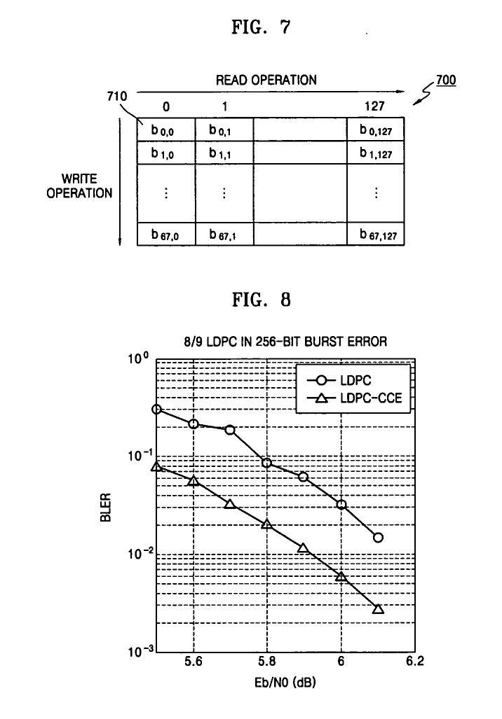

FIG. 7 illustrates an interleaver 700 on which an LDPC codeword interleaving is performed, according to an embodiment of the present invention. Referring to FIG. 7, b denotes a simplified representation of each block obtained by dividing the LDPC codewords illustrated in FIG. 6 into units of 256 bits. For instance, b_{0.0} 710 denotes a simplified representation of the LDPC codeword block 630 shown in FIG. 6. Here, the bit value of the 256 bits is the product, of the size value of the sub matrix, i.e., 128, and the number L=2 of blockwise columns the LDPC matrix 400 of FIG. 5, in which non-zero submatrices do not overlap with one another.

As described above, when using a value obtained by multiplying the size of each LDPC submatrix by the number of blockwise columns of the LDPC matrix in which non-zero submatrices do not overlap with one another as a unit of interleaving, it is also possible to improve the error correcting performance of encoding when performing interleaving by arranging non-zero LDPC submatrices in blockwise columns not to overlap with one another. FIG. 7 illustrates general interleaving in which codeword blocks are recorded in the interleaver 700 in the vertical direction and read from the interleaver 700 in the horizontal direction. As illustrated in FIG. 7, according to an aspect of the present invention, a long burst error can be corrected through general interleaving.

However, the type of interleaving used in the present invention is not limited thereto, that is, various types of interleaving may be used. For instance, the interleaving blocks are obtained by dividing the error correcting block by a multiple of each submatrix of the low-density parity check matrix. Also, interleaving may be performed on an error correcting block either in units of bits or units of bytes.

FIG. 8 is a graph comparing the conventional error correcting performance of encoding with that of an aspect of the present invention. In detail, FIG. 8 illustrates the block error rate (BLER) performance of a regular LDPC codeword, a coding rate r (=m/n=data length/codeword length) of which is 8/9 (=8192/9216 bits) and which is given a column weight of 3, when a 256-bit burst error occurs in the regular LDPC codeword. In FIG. 8, a y-axis denotes a BLER, and an x-axis denotes a bit energy-to-noise density (Eb/No) representing the quality of a digital signal. In FIG. 8, a conventional LDPC code is the same as an LDPC code according to an embodiment of the present invention, except that an LDPC matrix in which non-zero sub-blocks in a series of blockwise columns are arranged to overlap with one another. Referring to FIG. 8, the lower the BLER graph, the better the error correcting performance.

FIG. 8 reveals that when a 256-bit burst error occurs, it is possible to improve the error correcting performance using an LDPC code according to an aspect of the present invention, indicated by “LDPC-CCE” and “A”, than when using the conventional LDPC code, indicated by “∘”.

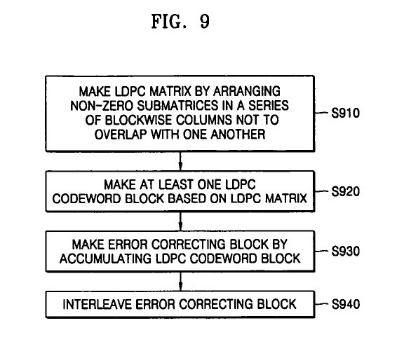

FIG. 9 is a flowchart illustrating LDPC encoding according to an embodiment of the present invention. Referring to FIG. 9, an LDPC matrix is generated such that non-zero submatrices in a series of blockwise columns are arranged not to overlap with one another (S910). Next, at least one LDPC codeword block is generated by making parity information based on the generated LDPC matrix (S920). Next, LDPC codeword blocks are accumulated to form an error correcting block (S930), and interleaving is performed on the error correcting block (S940).

In an LDPC encoding according to an aspect of the present invention, interleaving is performed in a communications/high-density recording medium system, using an LDPC matrix in which non-zero submatrices in blockwise columns are arranged not to overlap with one another, thereby improving the burst error correcting performance.

Also, since LDPC encoding according to an aspect of the present invention uses an interleaver with a simple structure, it is possible to simplify the construction of a memory address controller required for interleaving.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A low-density parity check encoding method comprising:
generating a low-density parity check matrix including submatrices by arranging non-zero submatrices in a series of blockwise columns such that the non-zero submatrices do not overlap with one another;
making at least one low-density parity check codeword block by generating parity information based on the low-density parity check matrix;
making an error correcting block by accumulating the low-density parity check codeword block; and
interleaving the error correcting block.

2. The low-density parity check encoding method of claim 1, wherein the non-zero submatrices of the low-density parity check matrix are arranged such that a cycle-4 phenomenon does not occur in the low-density parity check matrix.

3. The low-density parity check encoding method of claim 1, wherein each submatrix of the low-density parity check matrix is one of a unit matrix, a zero matrix and a shift matrix obtained by shifting the unit matrix by rows or columns.

4. The low-density parity check encoding method of claim 1, wherein the interleaving of the error correcting block comprises:
dividing the error correcting block into interleaving blocks, based on a size of each submatrix of the low-density parity check matrix; and
interleaving the error correcting block into units of the interleaving blocks.

5. The low-density parity check encoding method of claim 4, wherein the interleaving blocks are obtained by dividing the error correcting block by a multiple of each submatrix of the low-density parity check matrix.

6. The low-density parity check encoding method of claim 4, wherein the interleaving blocks are obtained by dividing the error correcting block by a value which is obtained by multiplying the size of each submatrix by a number of blockwise columns in which the non-zero submatrices of the low-density parity check matrix do not overlap with one another.

7. The low-density parity check encoding method of claim 1, wherein the interleaving of the error correcting block comprises interleaving the error correcting block into units of bytes.

8. The low-density parity check encoding method of claim 1, wherein the interleaving of the error correcting block comprises interleaving the error correcting block into units of bits.

9. The low-density parity check encoding method of claim 4, wherein the interleaving of the error correcting block comprises recording the interleaving blocks in a vertical direction and reading the interleaving blocks in a horizontal direction.

10. A low-density parity check encoding apparatus, comprising:
a low-density parity check encoder making a low-density parity check matrix having submatrices by arranging non-zero submatrices in a series of blockwise columns such that the non-zero submatrices do not overlap with one another, and generating at least one low-density parity check codeword block by generating parity information based on the low-density parity check matrix; and
an interleaver making an error correcting block by accumulating the low-density parity check codeword block, and interleaving the error correcting block.

11. The low-density parity check encoding apparatus of claim 10, wherein the non-zero submatrices of the low-density parity check matrix are arranged such that a cycle-4 phenomenon does not occur in the low-density parity check matrix.

12. The low-density parity check encoding apparatus of claim 10, wherein each submatrix of the low-density parity check matrix is one of a unit matrix, a zero-matrix and a shift matrix obtained by shifting the unit matrix by rows or columns.

13. The low-density parity check encoding apparatus of claim 10, wherein the interleaver divides the error correcting block into interleaving blocks based on a size of each submatrix of the low-density parity check matrix, and interleaves the error correcting block into units of the interleaving blocks.

14. The low-density parity check encoding apparatus of claim 13, wherein the interleaving blocks are obtained by dividing the error correcting block by a multiple of each submatrix of the low-density parity check matrix.

15. The low-density parity check encoding apparatus of claim 13, wherein the interleaving blocks are obtained by dividing the error correcting block by a value which is obtained by multiplying the size of each submatrix by a number of blockwise columns in which non-zero submatrices of the low-density parity check matrix do not overlap with one another.

16. The low-density parity check encoding apparatus of claim 10, wherein the interleaver interleaves the error correcting block into units of bytes.

17. The low-density parity check encoding apparatus of claim 10, wherein the interleaver interleaves the error correcting block into units of bits.

18. The low-density parity check encoding apparatus of claim 13, wherein the interleaver interleaves the error correcting block by recording the interleaving blocks in a vertical direction and reading them in a horizontal direction.
